(19) United States
(12) Patent Application Publication
(10) Pub. No.: US 2012/0112291 A1
(43) Pub. Date: May 10, 2012

(54) Semiconductor Apparatus And Manufacturing Method Thereof

(75) Inventor: Masahiko Yanagi, Osaka (JP)

(73) Assignee: SHARP KABUSHIKI KAISHA, Osaka (JP)

(21) Appl. No.: 13/288,051

(22) Filed: Nov. 3, 2011

(30) Foreign Application Priority Data
Nov. 5, 2010 (JP) 2010-249078
May 31, 2011 (JP) 2011-122617

(51) Int. Cl. H01L 27/092; H01L 21/762

(52) U.S. Cl. 257/369; 438/427; 257/E27.062; 257/E21.546

(57) ABSTRACT

A semiconductor apparatus according to the present invention has a P-type well and an N-type well, with impurity concentration of a high impurity concentration region deeper than the P-type well and the N-type well being from 1×10¹⁷ cm⁻³ to 1×10¹⁹ cm⁻³, and the apparatus comprises a first channel separating section for separating elements, and a depth of the first channel separating section is equal to or deeper than the high impurity concentration region.

This nonprovisional application claims priority under 35 U.S.C. §119(a) to Patent Application No. 2010-249078 filed in Japan on Nov. 5, 2010, and Patent Application No. 2011-122617 filed in Japan on May 31, 2011, the entire contents of which are hereby incorporated by reference.

### BACKGROUND OF THE INVENTION

1. Field of the Invention

The present invention relates to a high-voltage resisting semiconductor apparatus of a CMOS structure, such as a liquid crystal driver, and a manufacturing method thereof.

2. Description of the Related Art

For conventional semiconductor apparatuses of this type which operate under low power consumption and which have high voltage resistance characteristics, CMOS (Complementary Metal Oxide Semiconductors) complementarily using NMOSFET and PMOSFET are frequently used. While CMOS consume only low power, they also have a defect of causing latch up phenomenon, in which an external surge pulse triggers a thyristor to be turned on, causing a large current to continue flowing and resulting in breakdown, because a parasitic thyristor structure is formed theoretically in between NMOSFET and PMOSFET. This parasitic thyristor structure in between NMOSFET and PMOSFET will be specifically described with reference to FIGS. 13, 14(a) and 14(b).

FIG. 13 is a longitudinal cross sectional view, illustrating an essential part of a parasitic thyristor structure (PNPN structure) of a conventional semiconductor apparatus. FIGS. 14(a) and 14(b) are diagrams for describing an equalizing circuit of the PNPN structure in FIG. 13. FIG. 14(a) is a diagram schematically illustrating a PNPN structure. FIG. 14(b) is an equalizing circuit diagram of the PNPN structure.

As illustrated in FIG. 13, a conventional semiconductor apparatus 100 comprises a P-type well 102 and an N-type well 103 provided on a semiconductor substrate 101; and a channel separating section 104 is provided in the boundary of the P-type well 102 and the N-type well 103. An NMOS transistor 105 is provided in between channel separating sections 104 on the left side, and a PMOS transistor 106 is provided in between channel separating sections 104 on the right side. For the NMOS transistor 105, a gate electrode 108 is provided on the P-type well 102 with a gate oxide film 107 interposed therebetween. N+ regions 109 are provided respectively on both sides thereof, as a source region and a drain region. Further, for the PMOS transistor 106, a gate electrode 108 is provided on the N-type well 103 with a gate insulation film 107 interposed therebetween. On both sides thereof, P+ regions 110 are respectively provided as a source region and a drain region.

A parasitic thyristor structure is formed in the boundary of the P-type well 102 and the N-type well 103. This is equivalent to an NPN transistor 105 and a PNP transistor 106 connected with each other, as illustrated in FIG. 14(a). When the product of a current amplification factor hfenpn and a current amplification factor hfepnp of each transistor becomes 1 or greater and a first current starts to flow by an external surge or the like, the transistors start to amplify respective currents and continue to increase the currents, resulting in breakdown. As mentioned earlier, a thyristor structure is formed in between the NMOSFET 105 and the PMOSFET 106, as illustrated in FIG. 14(b), and thus, an external surge or the like triggers a thyristor to be turned on, causing a large current to continue flowing and resulting in breakdown. For this reason, it has been conventionally developed to prevent latch-up by reducing the amplification factor of the NMOSFET 105 or the PMOSFET 106, as disclosed in References 1, 2 and the like.

FIG. 15 is a longitudinal cross sectional view, illustrating an essential part of a P-type impurity doping step of CMOS LSI in a conventional semiconductor apparatus disclosed in Reference 1.

As illustrated in FIG. 15, it is contrived to reduce an amplification factor of an NPN transistor in a conventional semiconductor apparatus 200 by forming a channel separating section 203 in a boundary of a P-type well 201 and an N-type well 202, the channel separating section 203 being deeper than the P-type well 201, thereby obtaining a CMOS structure that is more resistant to latch-up.

FIG. 16 is a longitudinal cross sectional view illustrating an exemplary structure of an essential part of a conventional semiconductor apparatus disclosed in Reference 2.

As illustrated in FIG. 16, a conventional semiconductor apparatus 300 is a so-called BiCMOS in which bipolar transistors and CMOS coexist. In a boundary of a P-type well 301 and an N-type well 302 of a CMOS region thereof, a channel separating section 303 is provided, which is as deep as in the case in Reference 1. In addition, in a part deeper than the region of the N-type well 302, an N+ embedded region 305 with higher concentration is provided on a semiconductor substrate 304. In a part deeper than the region of the P-type well 301, a P+ embedded region 306 with higher concentration is provided on the semiconductor substrate 304. It is contrived to reduce an amplification factor hfe of each of an NMOS transistor 307 and a PMOS transistor 308, thereby obtaining a CMOS structure that is more resistant to latch-up.

Reference 1: Japanese Laid-Open Publication No. 60-226136

Reference 2: Japanese Patent No. 3,244,412

### SUMMARY OF THE INVENTION

In the conventional semiconductor apparatus 200 disclosed in Reference 1, even if a deep channel separating section 203 is provided, electrons pass through a region that is deeper than the channel separating section 203. Thus, the amplification factor hfe of the NPN transistor remains high, and the structure is not so effective. According to simulations performed by the inventors, the amplification factor hfe was reduced as much as half even with 4 μm to 6 μm etching of the channel depth. When a channel was etched to the depth of 6 μm and a substrate impurity concentration was about 10¹⁵, an actual value at the 6 μm channel depth showed a mere reduction of about 80% amplification factor hfe, as illustrated in a measurement point A of FIG. 2. With this result, it is not possible to obtain a CMOS structure that is resistant to latch-up.

In the conventional semiconductor apparatus 300 disclosed in Reference 2, although it is possible to obtain a CMOS structure that is more resistant to latch-up by providing an N+ embedded region 305 and a P+ embedded region 306, it is necessary to form such an N+ embedded region 305 and a P+ embedded region 306 deep in the well region above the semiconductor substrate 304 by using two photolithography steps and two impurity implanting steps in advance. In addition, epitaxial growth is also necessary. While there is no increase in the number of steps for the BiCMOS structure, in which an embedded layer for a bipolar transistor is formed from the first, the CMOS structure is problematic due to the increase in the number of steps, causing the steps to be more complicated and also causing an increase in the manufacturing cost.

Moreover, apart from the latch-up due to a parasitic thyristor of the CMOS structure, it is not possible at all to prevent another parasitic NPN transistor to be formed in an NMOS structure within a P-type well as illustrated in FIG. 7, and to prevent a large current from flowing in the parasitic NPN transistor by an external surge acting as a trigger.

The present invention is intended to solve the conventional problems described above. It is an objective of the present invention to provide a semiconductor apparatus, and a manufacturing method thereof, capable of obtaining a CMOS structure and an NMOS structure that are more resistant to latch-up and that can be manufactured with simple steps.

A semiconductor apparatus having a P-type well and an N-type well according to the present invention is provided, with impurity concentration of a high impurity concentration region deeper than the P-type well and the N-type well being from 1×10¹⁷ cm⁻³ to 1×10¹⁹ cm⁻³, and the apparatus comprises a first channel separating section for separating elements, a depth of the first channel separating section being equal to or deeper than the high impurity concentration region, thereby achieving the objective described above.

Preferably, in a semiconductor apparatus of a CMOS structure having a P-type well and an N-type well according to the present invention, the apparatus comprises a second channel separating section for separating elements, the first channel separating section being at a boundary of the N-type well and the P-type well, a depth of the first channel separating section being deeper than a depth of the second channel separating section.

Still preferably, in a semiconductor apparatus according to the present invention: the apparatus comprises a second channel separating section for separating elements; the first channel separating section is arranged, in a plane view, at least either between an N-type region connected to a power source voltage output terminal and an N-type region of an NMOS transistor, or between a P-type region connected to the power source voltage output terminal and a P-type region of a PMOS transistor, at least within either the P-type well or the N-type well, or arranged in such a manner to surround at least either of the N-type region or the P-type region connected to the power source voltage output terminal; and a depth of the first channel separating section is deeper than a depth of the second channel separating section.

A semiconductor apparatus of a CMOS structure having a P-type well and an N-type well according to the present invention is provided, with impurity concentration of a high impurity concentration region deeper than the P-type well and the N-type well being from 1×10¹⁷ cm⁻³ to 1×10¹⁹ cm⁻³, and the apparatus comprises a first channel separating section and a second channel separating section for separating elements, the first channel separating section being at a boundary of the N-type well and the P-type well, a depth of the first channel separating section being deeper than a depth of the second channel separating section, a depth of the first channel separating section being equal to or deeper than the high impurity concentration region, thereby achieving the objective described above.

Still preferably, in a semiconductor apparatus according to the present invention: an epitaxial layer is provided on a semiconductor substrate; the P-type well and the N-type well are provided in an upper part of the epitaxial layer; an NMOS transistor is provided within the P-type well in between the second channel separating sections; and a PMOS transistor is provided within the N-type well in between the second channel separating sections, thereby achieving the objective described above.

Still preferably, in a semiconductor apparatus according to the present invention, the semiconductor substrate is the high impurity concentration region, or the high impurity concentration region is arranged in the semiconductor substrate.

Still preferably, in a semiconductor apparatus according to the present invention, a partial region of the epitaxial layer thermally diffused from the semiconductor substrate to the epitaxial layer is the high impurity concentration region.

Still preferably, in a semiconductor apparatus according to the present invention, the depth of the first channel separating section is deeper than a depth reaching a region of the semiconductor substrate, or the depth of the first channel separating section is deeper than a depth of the partial region of the epitaxial layer thermally diffused from the semiconductor substrate.

Still preferably, in a semiconductor apparatus according to the present invention, a tip portion or a bottom surface portion of the first channel separating section reaches at least an upper limit boundary section of the high impurity concentration region.

Still preferably, in a semiconductor apparatus according to the present invention, the tip portion or the bottom surface portion of the first channel separating section contacts or is in the high impurity concentration region, by 0 to 2 μm.

Still preferably, in a semiconductor apparatus according to the present invention, the impurity concentration of the high impurity concentration region is from 1×10¹⁸ cm⁻³ to 1×10¹⁹ cm⁻³.

Still preferably, in a semiconductor apparatus according to the present invention, the impurity concentration of the high impurity concentration region is from 5×10¹⁸ cm⁻³ to 1×10¹⁹ cm⁻³.

Still preferably, in a semiconductor apparatus according to the present invention, the impurity is either a P-type impurity or an N-type impurity.

Still preferably, in a semiconductor apparatus according to the present invention, the P-type impurity is boron or indium, and the N-type impurity is phosphor, arsenic or antimony.

Still preferably, in a semiconductor apparatus according to the present invention, the first channel separating section is formed deeper than the bottom surface portion of the second channel separating section.

Still preferably, in a semiconductor apparatus according to the present invention, the first channel separating section is arranged in between an NMOS transistor formed within the P-type well and a PMOS transistor formed within the N-type well, or is arranged in such a manner to surround the PMOS transistor.

A manufacturing method for a semiconductor apparatus of a CMOS structure having an 1-type well and a P-type well according to the present invention comprises: an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region; a first channel forming step of forming a first channel in a boundary section of the N-type well and the P-type well with a depth as deep as the epitaxial layer or with a depth penetrating the epitaxial layer and reaching the high impurity concentration region of the first semiconductor substrate or the second semiconductor substrate; a second channel forming step of forming a second channel shallower than the first channel; a channel separating section forming step of forming a first channel separating section and a second channel separating section, for separating elements, by filling the first channel and the second channel with an identical insulating material or different insulating materials, or by forming an insulation film on inner and bottom surfaces of the first channel and the second channel and subsequently filling a conductive material into the interior thereof; and a well region forming step of forming the N-type well and the P-type well shallower than the depth of the first channel and deeper than the depth of the second channel, thereby achieving the objective described above.

A manufacturing method for a semiconductor apparatus of a CMOS structure having an N-type well and a P-type well according to the present invention comprises: an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region; a first channel forming step of forming a first channel in a boundary section of the N-type well and the P-type well with a depth shallower than the thickness of the epitaxial layer; a second channel forming step of forming a second channel shallower than the first channel; a channel separating section forming step of forming a first channel separating section and a second channel separating section, for separating elements, by filling the first channel and the second channel with an identical insulating material or different insulating materials, or by forming an insulation film on inner and bottom surfaces of the first channel and second channel and subsequently filling a conductive material into the interior thereof; a well region forming step of forming the N-type well and the P-type well shallower than the depth of the first channel and deeper than the depth of the second channel; and a thermal treatment step of diffusing impurities from the first semiconductor substrate or the second semiconductor substrate to the epitaxial layer to allow a tip portion of the first channel separating section to reach the high impurity concentration region thereof, thereby achieving the objective described above.

A manufacturing method for a semiconductor apparatus having an N-type well and a P-type well according to the present invention comprises: an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region; a first channel forming step of forming a first channel, at the same depth as the epitaxial layer or at a depth penetrating the epitaxial layer and reaching the high impurity concentration region of the first semiconductor substrate or the second semiconductor substrate, at least either between an N+ region connected to a power source voltage output terminal and an N+ region of an output NMOS transistor, or between a P-type region connected to the power source voltage output terminal and a P-type region of a PMOS transistor, or in such a manner to surround at least either of the N+ region or the P-type region connected to the power source voltage output terminal; a second channel forming step of forming a second channel shallower than the first channel; a channel separating section forming step of forming a first channel separating section and a second channel separating section, for separating elements, by filling the first channel and the second channel with an identical insulating material or different insulating materials, or by forming an insulation film on inner and bottom surfaces of the first channel and second channel and subsequently filling a conductive material into the interior thereof; and a well region forming step of forming the N-type well and the P-type well shallower than the first channel and deeper than the second channel, thereby achieving the objective described above.

A manufacturing method for a semiconductor apparatus having an N-type well and a P-type well according to the present invention comprises: an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region; a first channel forming step of forming a first channel, at a depth shallower than the thickness of the epitaxial layer, at least either between an N+ region connected to a power source voltage output terminal and an N+ region of an NMOS transistor, or between a P-type region connected to the power source voltage output terminal and a P-type region of a PMOS transistor, or in such a manner to surround at least either of the N+ region or the P-type region connected to the power source voltage output terminal; a second channel forming step of forming a second channel shallower than the first channel; a channel separating section forming step of forming a first channel separating section and a second channel separating section, for separating elements, by filling the first channel and the second channel with an identical insulating material or different insulating materials, or by forming an insulation film on inner and bottom surfaces of the first channel and second channel and subsequently filling a conductive material into the interior thereof; a well region forming step of forming the N-type well and the P-type well shallower than the first channel and deeper than the second channel; and a thermal treatment step of diffusing impurities, by thermal treatment, from the first semiconductor substrate or the second semiconductor substrate to the epitaxial layer to allow a tip portion of the first channel separating section to reach the high impurity concentration region thereof, thereby achieving the objective described above.

Preferably, in a manufacturing method for a semiconductor apparatus according to the present invention, the depth of the first channel separating section is formed equal to or deeper than a depth reaching a region of the first semiconductor substrate or the second semiconductor substrate, or equal to or deeper than a depth of a partial region of the epitaxial layer thermally diffused from the first semiconductor substrate or the second semiconductor substrate.

Still preferably, in a manufacturing method for a semiconductor apparatus according to the present invention, the first channel separating section is formed in such a manner to allow the tip portion or a bottom surface portion thereof to reach at least an upper limit boundary section of the high impurity concentration region.

Still preferably, in a manufacturing method for a semiconductor apparatus according to the present invention, the first channel separating section is formed in such a manner to allow the tip portion or the bottom surface portion thereof contact or be in the high impurity concentration region, by 0 to 2 μm.

Still preferably, in a manufacturing method for a semiconductor apparatus according to the present invention, the impurity concentration of the high impurity concentration region is from 1×10¹⁸ cm⁻³ to 1×10¹⁹ cm⁻³.

Still preferably, in a manufacturing method for a semiconductor apparatus according to the present invention, the impurity concentration of the high impurity concentration region is from 5×10¹⁷ cm⁻³ to 1×10¹⁹ cm⁻³.

Still preferably, in a manufacturing method for a semiconductor apparatus according to the present invention, the impurity is either a P-type impurity or an N-type impurity.

The functions of the present invention having the structures described above will be described hereinafter.

In the present invention, in a semiconductor apparatus having an N-type well and a P-type well; impurity concentration of a high impurity concentration region deeper than the P-type well and the N-type well is from 1×10¹⁷ cm⁻³ to 1×10¹⁹ cm⁻³; the apparatus comprises a first channel separating section and a second channel separating section for separating elements; a depth of the first channel separating section is deeper than a depth of the second channel separating section; and a depth of the first channel separating section is equal to or deeper than a high impurity concentration region. Specifically, a deep first channel separating section lies at a well boundary, and the depth of the first channel separating section is at a depth reaching a high impurity concentration region with impurity concentration from 1×10¹⁷ cm⁻³ to 1×10¹⁹ cm⁻³.

Thereby, a semiconductor substrate with high impurity concentration of 1×10¹⁷ cm⁻³ to 1×10¹⁹ cm⁻³ is used, and a tip portion of a first channel separating section, provided at a well boundary of a P-type well and an N-type well of a CMOS structure, is formed at a depth reaching the high impurity concentration region. Thus, electrons will not pass though a region that is deeper than the first channel separating section as happens conventionally. Further, it becomes unnecessary to newly embed an N+ embedded layer or a P+ embedded layer deep in the substrate within the well region as conventionally done. As a result, a CMOS structure that is more resistant to latch-up can be obtained using a simple method, and a semiconductor apparatus excellent in both cost effectiveness and performance can be obtained.

Further, the present invention is capable of preventing an on-state of a parasitic thyristor in a well boundary, and in addition to or apart from this, the present invention is further capable of preventing an on-state of a parasitic NMOS transistor. Thus, a CMOS structure that is more resistant to latch-up and that is manufactured with simple steps, and in addition to or apart from this, an NMOS structure that is more resistant to latch-up and that is manufactured with simple steps, can be obtained.

As described above, according to the present invention, a semiconductor substrate with high impurity concentration of 1×10¹⁷ cm⁻³ to 1×10¹⁹ cm⁻³ is used, and a tip portion of a first channel separating section, provided at a well boundary of a P-type well and an N-type well of a CMOS structure, is formed at a depth reaching the high impurity concentration region. Thus, electrons will not pass though a region that is deeper than the first channel separating section as happens conventionally. Further, it becomes unnecessary to newly embed an N+ embedded layer or a P+ embedded layer deep in the substrate within the well region as conventionally done. As a result, a CMOS structure that is more resistant to latch-up can be obtained using a simple method, and a semiconductor apparatus excellent in both cost effectiveness and performance can be obtained.

Further, in addition to or apart from an on-state preventing function of a parasitic thyristor at a well boundary, an on-state of a parasitic NMOS transistor can be further prevented. Thereby, a CMOS structure more resistant to latch-up can be obtained with simple steps, and in addition to or apart from this, an NMOS structure more resistant to latch-up can be obtained with simple steps .

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view illustrating an exemplary structure of an essential part of a high-voltage resisting semiconductor apparatus in Embodiment 1 of the present invention.

FIG. 2 is a diagram illustrating the relationship between impurity concentration and amplification factor.

FIGS. 3(a) to (c) are each a longitudinal cross sectional view illustrating an exemplary structure of an essential part for describing each manufacturing step (part 1) of a manufacturing method for a semiconductor apparatus in FIG. 1.

FIGS. 4(d) to f) are each a longitudinal cross sectional view illustrating an exemplary structure of an essential part for describing each manufacturing step (part 2) of a manufacturing method for a semiconductor apparatus in FIG. 1.

FIG. 5 is a longitudinal cross sectional view illustrating an exemplary structure of an essential part of a high-voltage resisting semiconductor apparatus according to Embodiment 2 of the present invention.

FIG. 6 is a plane view schematically illustrating a structure in a plane view of a high-voltage resisting semiconductor apparatus in FIG. 1 or 5.

FIG. 7 is a longitudinal cross sectional view of an essential part of a semiconductor apparatus, illustrating an exemplary equalizing circuit of a parasitic NPN transistor formed within a P-type well.

FIG. 8 is a longitudinal cross sectional view illustrating an exemplary structure of an essential part of a high-voltage resisting semiconductor apparatus according to Embodiment 3 of the present invention.

FIG. 9 is a plane view schematically illustrating an example of a structure in a plane view of a high-voltage resisting semiconductor apparatus in FIG. 8.

FIG. 10 is a plane view schematically illustrating an example of a structure in a plane view of a single N+ diode.

FIG. 11 is a plane view schematically illustrating an example of a structure in a plane view of two N+ diodes in parallel to each other.

FIG. 12(a) is a circuit diagram illustrating an equalizing circuit of a single N+ diode in FIG. 10. FIG. 12(b) is a circuit diagram illustrating an equalizing circuit of two N+ diodes in parallel to each other in FIG. 11.

FIG. 13 is a longitudinal cross sectional view, illustrating an essential part of a parasitic thyristor structure (PNPN structure) of a conventional semiconductor apparatus.

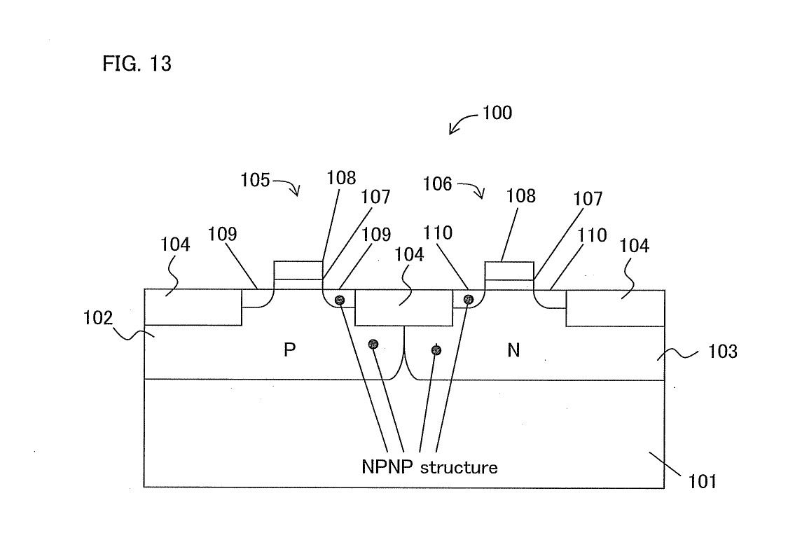

FIG. 14 is a diagram describing an equalizing circuit of a PNPN structure in FIG. 13, where FIG. 14(a) is a diagram for describing a PNPN structure, and FIG. 14(b) is an equalizing circuit diagram of the PNPN structure.

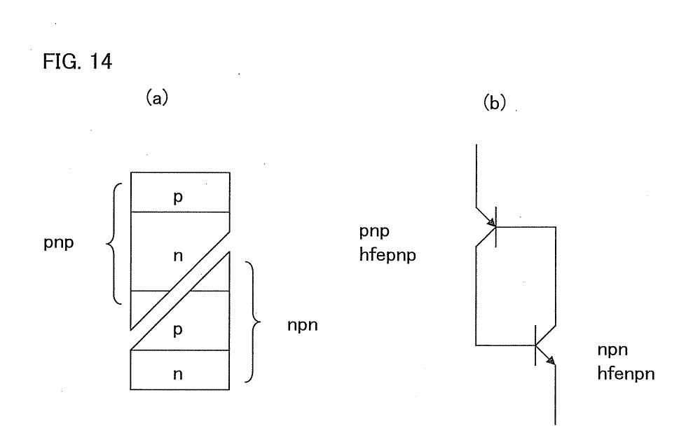

FIG. 15 is a longitudinal cross sectional view, illustrating an essential part of a P-type impurity doping step of CMOSLSI in a conventional semiconductor apparatus disclosed in Reference 1.

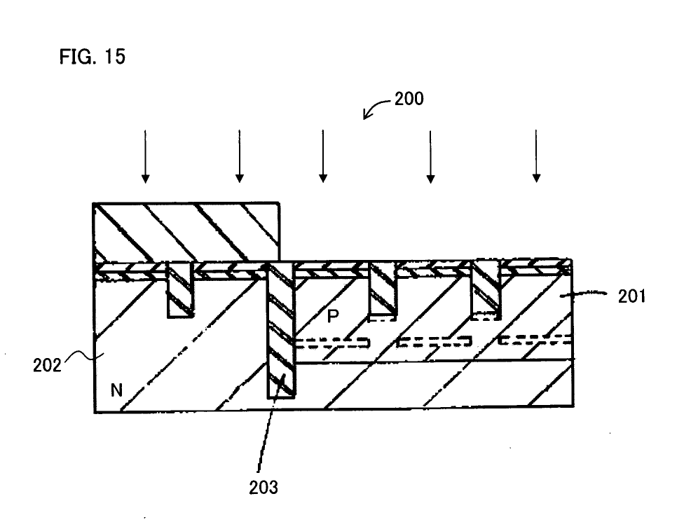

FIG. 16 is a longitudinal cross sectional view illustrating an exemplary structure of an essential part of a conventional semiconduct or apparatus disclosed in Reference 2.

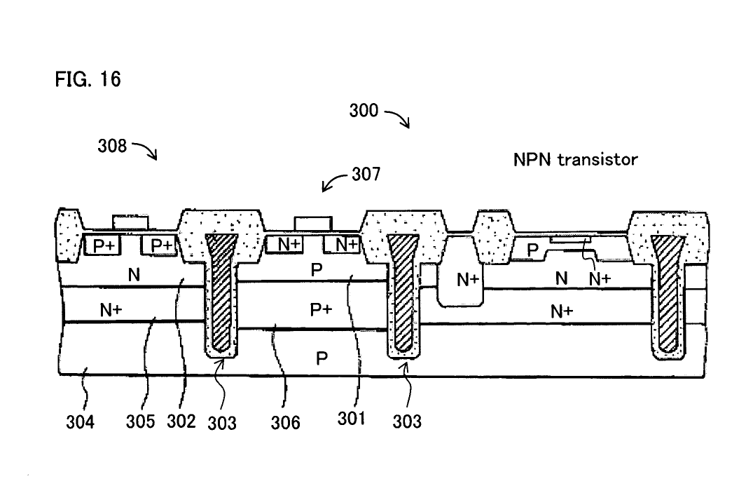

1, 1A, 1B semiconductor apparatus (first semiconductor substrate)
2 semiconductor substrate with impurity concentration of 1×10¹⁷ cm⁻³ or more
3 epitaxial layer
3a high impurity concentration region
4 P-type well
5 N-type well
6 channel separating section (second channel separating section)
7, 7A NMOS transistor
8 PMOS transistor
9 gate insulation film
10 gate electrode
11 N+ region
12 P+ region
13, 13A channel separating section (first channel separating section)
13a trench (first channel)

### DESCRIPTION OF THE PREFERRED EMBODIMENTS

Hereinafter, Embodiments 1 to 3 of a high-voltage resisting semiconductor apparatus and a manufacturing method thereof according to the present invention will be described in detail with reference to the accompanying figures. Thickness, length and the like of elements in each figure should not be limited to those illustrated in the figures from the viewpoint of the figure preparation.

### Embodiment 1

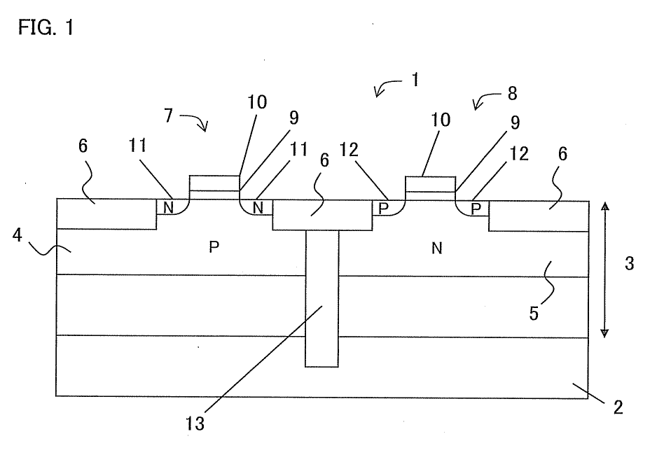

FIG. 1 is a longitudinal cross sectional view illustrating an exemplary structure of an essential part of a high-voltage resisting semiconductor apparatus in Embodiment 1 of the present invention.

In FIG. 1, a high-voltage resisting semiconductor apparatus 1 according to Embodiment 1 comprises an epitaxial layer 3 formed by epitaxial growth on a semiconductor substrate 2 of high impurity concentration. A P-type well 4 and an N-type well 5 are provided in an upper part of the epitaxial layer 3. A channel separating section 6 (LOCOS region) for separating elements is provided above boundaries of the P-type well 4 and the N-type well 5. The channel separating section 6 (LOCOS region) is used, not only for the boundary, but also for separating elements. As described above, the semiconductor apparatus 1 is a CMOS structure having a P-type well 4 and an N-type well 5, where an NMOS transistor 7 is provided in between the channel separating sections 6 (LOCOS regions) on the left side, and a PMOS transistor 8 is provided in between the channel separating sections 6 (LOCOS regions) on the right side. In the NMOS transistor 7, a gate electrode 10 is provided above the P-type well 4 with a gate insulation film 9 interposed therebetween, and N+ regions 11 are respectively provided on both sides thereof, as a source region and a drain region. Further, in the PMOS transistor 8, a gate electrode 10 is provided above the N-type well 5 with a gate insulation film 9 interposed therebetween, and P+ regions 12 are respectively provided on both sides thereof, as a source region and a drain region.

The semiconductor substrate 2 of high impurity concentration is formed such that the concentration of the impurity (N-type or P-type) is higher than 1×10¹⁸ cm⁻³. The high impurity concentration region of the semiconductor substrate 2 is located deeper than the P-type well 4 or the N-typewell 5. The channel separating section 6 (LOCOS region) located at the boundary of the P-type well 4 and the N-type well 5 is located at a region shallower than the deepest point of the P-type well 4 and the N-type well 5. A channel separating section 13 is formed at a location even deeper than the channel separating section 6 (LOCOS region). The channel separating section 13 is formed at a position deeper than the channel separating section 6, and the depth of the channel separating section 13 is deeper than the region of the semiconductor substrate 2 of high impurity concentration of greater than 1×10¹⁸ cm⁻³. Specifically, there lies the channel separating section 13 deep in the well boundary, and the depth of the channel separating section 13 is the depth reaching the region of high impurity concentration of greater than or equal to 1×10¹⁸ cm⁻³.

As described above, the inventors have found it possible to obtain a CMOS structure which has an adequately reduced amplification factor hfe and which is more resistant to latch-up, with a channel structure in which the concentration of the part deeper than the well depth, that is, the impurity concentration of the semiconductor substrate 2, is greater than or equal to 1×10¹⁸ cm⁻³ and the depth of the channel separating section 13 of the well boundary is deeper than the upper region of the semiconductor substrate 2 with impurity concentration of greater than or equal to 1×10¹⁸ cm⁻³.

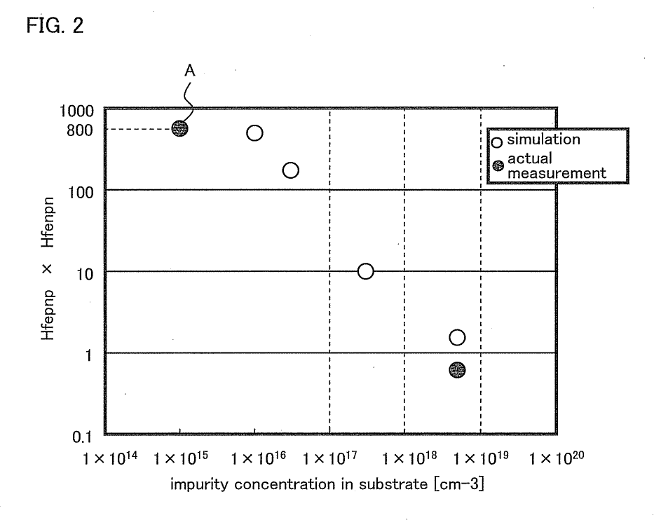

FIG. 2 is a diagram illustrating the relationship between impurity concentration and amplification factor, illustrating a result of simulation and actual measurement.

As can be seen from FIG. 2, as the impurity concentration (N-type or P-type) at the tip portion of the channel separating section 13 becomes higher than 1×10¹⁸ cm⁻³, the amplification factor hfe becomes adequately smaller, thereby obtaining a CMOS structure more resistant to latch-up. Preferably, the impurity concentration (N-type or P-type) at the tip portion of the channel separating section 13 becomes higher than 5×10¹⁸ cm⁻³, the amplification factor hfe becomes adequately smaller, thereby obtaining a CMOS structure more resistant to latch-up. Further, in order to achieve such a CMOS structure more resistant to latch-up, a wafer or a semiconductor substrate 2 of the impurity concentration greater than or equal to 1×10¹⁸ cm⁻³. preferably 5×10¹⁸ cm⁻³ or more, is used, and a low impurity concentration epitaxial layer 3 is grown thereon, so that the desired CMOS structure can be obtained. The epitaxial layer 3 may be thick enough with a depth adequate to form a well. For example, the thickness of 5 μm to 7 μm may be adequate. A trench 13a to be a channel separating section 13 may be formed using RIE (reactive ion etching) , the trench 13a penetrating the epitaxial layer 3 and reaching the semiconductor substrate 2. Compared to the case of Reference 2, it is only necessary to prepare a semiconductor substrate 2 of high impurity concentration of 1×10¹⁸ cm⁻³ or more. This results in eliminating photolithography for forming an embedded layer and its impurity ion implanting step of Reference 2, and the steps can be simplified. Accordingly, the manufacturing cost can also be lowered. Further, it will be meaningless if the upper limit of the impurity concentration (N-type or P-type) exceeds 1×10¹⁹ cm⁻³ since the amplification factor hfe becomes 1 or less, as can be understood from FIG. 2. Therefore, the impurity concentration (N-type or P-type) of the region to which the tip portion of the channel separating section 13 reaches is from 1×10¹⁸ cm⁻³ to 1×10¹⁹ cm⁻³, and preferably from 5×10¹⁸ cm⁻³ to 1×10¹⁹ cm⁻³.

A manufacturing method for a high-voltage resisting semiconductor apparatus 1 having the structures above will be described hereinafter.

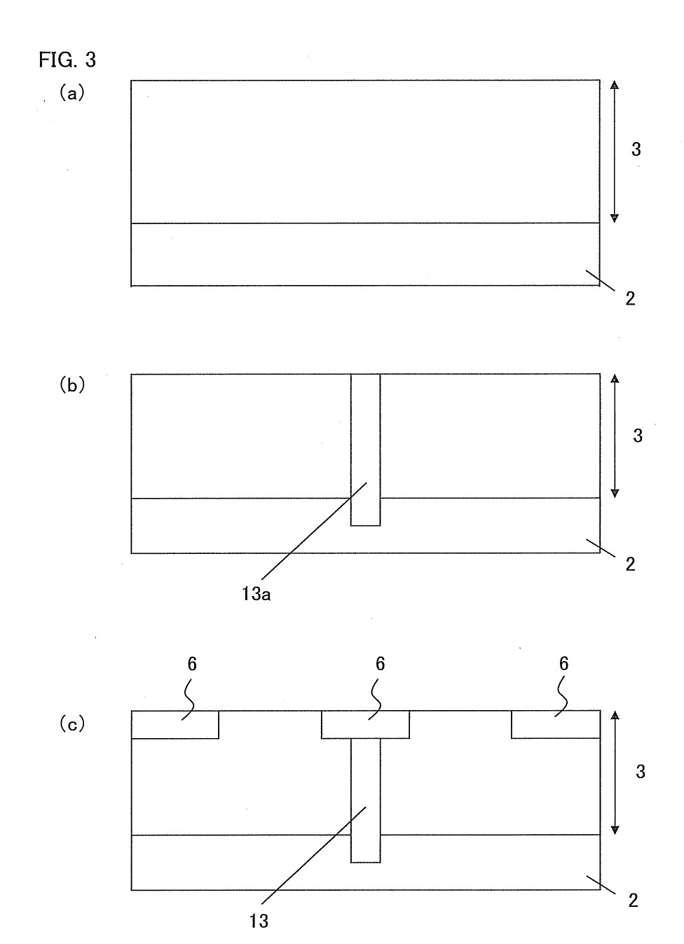

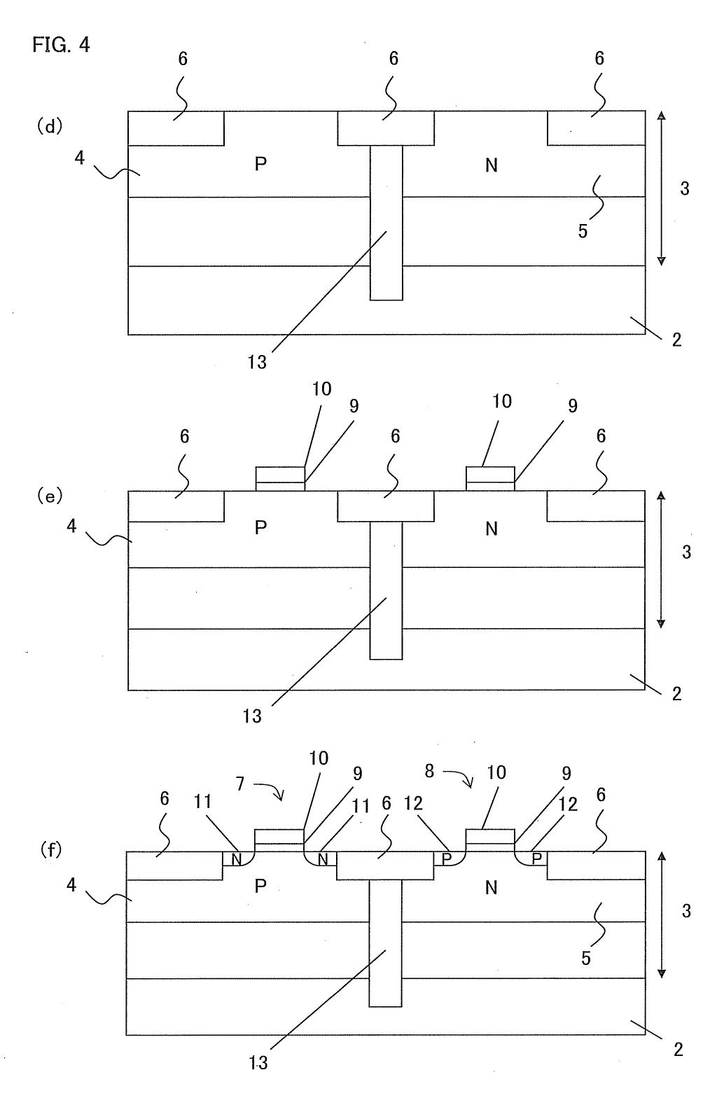

FIGS. 3(a) to 3(c) and FIGS. 4(d) to 4(f) are each a longitudinal cross sectional view of an essential part, illustrating each manufacturing step in a manufacturing method for the semiconductor apparatus 1 in FIG. 1.

First, as illustrated in FIG. 3(a) , a silicon (Si) substrate is used as a semiconductor substrate 2 with the impurity concentration from 1×10¹⁸ cm⁻³ to 1×10¹⁹ cm⁻³, and an epitaxial layer 3 is grown on the silicon substrate. Possible impurities implanted into the silicon substrate are boron or indium as the P-type, and phosphor, arsenic, or even antimony as the N-type . The thickness of the epitaxial layer 3 is formed to be, for example, 4 μm to 8 μm, which is adequate to form a well.

Next, as illustrated in FIG. 3(b), a trench 13a is formed at a position which will be a boundary of the well in a later step. The trench 13a of the well boundary is formed by etching using an RIE method. When the depth of the epitaxial layer 3 is 4 μm, the depth of the trench 13a is etched from 4 μm to 5 μm. When the depth of the epitaxial layer 3 is 6 μm, the depth of the trench 13a is etched from 6 μm to 7 μm. Specifically, the depth of the trench 13a may be a depth which allows the tip portion of the trench 13a to penetrate the epitaxial layer 3 and reach a high impurity concentration region of the silicon (Si) substrate. Herein, the tip portion of the trench 13a is at least 1 μm deep into the high impurity concentration region of the silicon (Si) substrate.

After forming the trench 13a, an insulation film for separating elements may be filled within the trench 13a. Alternatively, an oxide by thermal oxidation or a CVD oxide may be formed on side walls and a bottom surface of the trench 13a at a thickness of 10 μm to 50 μm, and then a conductive material, such as polycrystal silicon, may be filled therein.

Subsequently, as illustrated in FIG. 3(c), a channel separating section 6 is formed at each position, such as in between transistors, for separating elements. The channel separating section 6 is formed using a conventional technique, after the etching and removing of silicon on the side closer to the front surface of the epitaxial layer 3, forming of a recess portion in a predetermined region, and filling of an insulation film within the recess portion of the predetermined region. As the channel separating section 6 is formed, a channel separating section 13 is completed below the channel separating section 6. The channel separating section 6 may also be formed using a LOCOS method (Local Oxidation of Silicon).

Thereafter, as illustrated in FIG. 4(d) , a P-type well 4 and an N-type well 5 are formed in the upper part of the epitaxial layer 3 with the channel separating section 13 as a boundary. For a method for forming a P-type well 4 and a N-type well 5, for example, firstly, a photolithograph is used, and a P-type impurity, or boron, is implanted for several times for the dose of 1×10¹² cm² to 1×10¹³ cm², with one to three kinds of energy of 200 KeV to 800 KeV, with a resist mask having an opening for forming a P-type well 4. As a result, a region for a P-type well 4 can be formed. Next, using a resist mask with an opening for forming an N-type well 5, an N-type impurity, or phosphor, is implanted for the dose of 1×10¹² cm² to 1×10¹³ cm², with one to three kinds of energy of 400 KeV to 2 MeV. As a result, a region for an N-type well 5 can be formed.

After these ion implantations, a thermal diffusion treatment is performed to form a P-type well 4 and an N-type well 5. This thermal diffusion treatment may be performed in inactive gas at 950° C. for 60 minutes, or the thermal diffusion treatment may be combined with a thermal treatment during thermal oxidation for forming a gate insulation film, which will be explained later.

Subsequently, as illustrated in FIG. 4(e) , a gate insulation film 9 is formed on the epitaxial layer 3, and a gate electrode 10 is formed thereon. The gate insulation film 9 is formed with a thickness of 20 nm to 40 nm, for example, on the epitaxial layer 3, using a thermal oxidation method. The gate electrode 10 is formed such that polycrystal is accumulated with a thickness of 150 nm to 250 nm on the gate insulation film 9 using a CVD method, and then the gate electrode 10 and the gate insulation film 9 are etched in a predetermined shape using RIE, with a photoresist patterned in a predetermined shape as a mask.

Further, as illustrated in FIG. 4(f), N+ regions 11 are formed in regions in the P-type well 4 and on both sides of the gate electrode 10, and P+ regions 12 are formed in regions in the N-type well 5 and on both sides of the gate electrode 10. As a result, a channel separating section 13 is formed in the boundary of the P-type well 4 and the

N-type well 5, and with the tip portion thereof reaching a high impurity concentration region, an NMOS transistor 7 and a PMOS transistor 8 of a CMOS structure are formed.

In the NMOS transistor 7, the gate electrode 10 is provided on the P-type well 4 with the gate insulation film 9 interposed therebetween, and the N+ regions 11 are provided on both sides thereof, as a source region and a drain region. Further, in the PMOS transistor 8, the gate electrode 10 is provided on the N-type well 5 with the gate insulation film 9 interposed therebetween, and the P+ regions 12 are provided on both sides thereof, as a source region and a drain region.

While the N+ regions 11 and the P+ regions 12 are such that the concentrations of the impurities are equal in FIG. 1, they maybe a so-called LDD (Lightly Doped Drain) region consisting of two types of regions with different impurity concentrations.

For the subsequent step, similar to a manufacturing method for a conventional semiconductor apparatus, a wiring layer is formed to be connected to the NMOS transistor 7 and the PMOS transistor 8 of a CMOS structure, thus a CMOS circuit is completed.

In summary, the manufacturing method for the semiconductor apparatus 1 is a manufacturing method for a semiconductor apparatus 1 of a CMOS structure having an N-type well 5 and a P-type well 4, comprising: an epitaxial growth step of growing an epitaxial layer 3 on a semiconductor substrate 2, as a first semiconductor substrate which is a high impurity concentration region with impurity concentration of 1×10¹⁷ cm⁻³ to 1×10¹⁹ cm⁻³, preferably 1×10¹⁸ cm⁻³ to 1×10¹⁹ cm⁻³, and more preferably 5×10¹⁸ cm⁻³ to 1×10¹⁹ cm⁻³; a first channel forming step of forming a first trench 13a in a boundary section of the N-type well 5 and the P-type well 4 with a depth as deep as the epitaxial layer 3 or with a depth penetrating the epitaxial layer 3 and reaching the high impurity concentration region of the semiconductor substrate 2; a second channel forming step of forming a second channel shallower than the first trench 13a; a channel separating section forming step of forming a channel separating section 13 as a first channel separating section and a channel separating section 6 as a second channel separating section, for separating elements, by filling the first trench 13a and the second channel with an identical insulating material or different insulating materials, or by forming an insulation film on inner and bottom surfaces of the trench 13a and second channel and subsequently filling a conductive material into the interior thereof; and a well region forming step of forming the N-type well 5 and the P-type well 4 shallower than the depth of the first trench 13a and deeper than the depth of the second channel.

From the foregoing, according to Embodiment 1, a semiconductor substrate 2 with high impurity concentration of 1×10¹⁷ cm⁻³ to 1×10¹⁹ cm⁻³ is used, and a tip portion of a channel separating section 13 provided in the boundary of a P-type well 4 and an N-type well 5 of a CMOS structure is formed deeply to reach the high impurity concentration region (penetrating an epitaxial layer 3 and reaching the region of the semiconductor substrate 2). As a result, electrons will not pass though a region that is deeper than the channel separating section 13 (below the channel separating section 13) as happens conventionally. Further, it becomes unnecessary to embed an N+ embedded layer or a P+ embedded layer deep in the substrate within a well region as conventionally done. A CMOS structure that is more resistant to latch-up can be obtained using a simple method, and a semiconductor apparatus 1 excellent in both cost effectiveness and performance can be obtained.

In Embodiment 1, a case has been described where a tip portion of the channel separating section 13, formed at the boundary of the P-type well 4 and N-type well 5, is formed deep enough to reach the high impurity concentration region of the semiconductor substrate 2. However, without the limitation to this, even if the tip portion of the channel separating section 13, formed at the boundary of the P-type well 4 and N-type well 5, does not reach the high impurity concentration region of the semiconductor substrate 2, but extends up to the middle of the epitaxial layer 3, a similar effect as Embodiment 1 can be obtained if the high impurity concentration region of the semiconductor substrate 2 is diffused and expanded by thermal treatment, and the tip portion of the channel separating section 13 reaches the diffused and expanded high impurity concentration region. Details of this case will be described as Embodiment 2.

### Embodiment 2

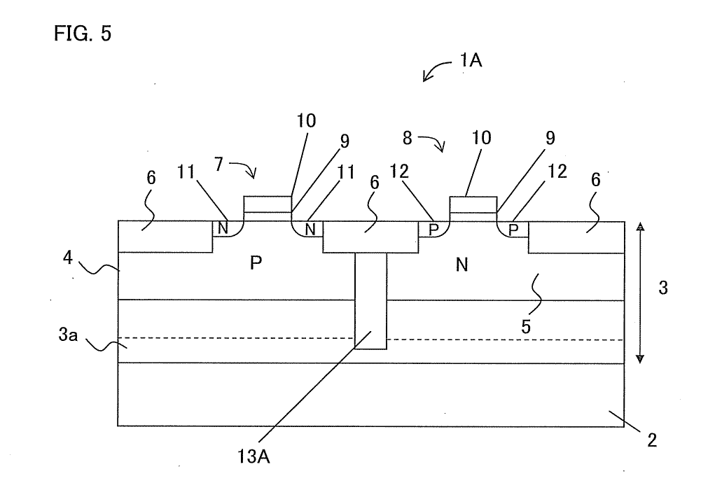

FIG. 5 is a longitudinal cross sectional view illustrating an exemplary structure of an essential part of a high-voltage resisting semiconductor apparatus according to Embodiment 2 of the present invention. The same reference numerals are used for the structural members that indicate the same functional effects as those of the structural members in FIG. 1.

In FIG. 5, a high-voltage resisting semiconductor apparatus 1A according to Embodiment 2 comprises an epitaxial layer 3 formed on a semiconductor substrate 2 of high impurity concentration. A P-type well 4 and an N-type well 5 are provided in an upper part of the epitaxial layer 3. A channel separating section 6 (LOCOS region) for separating elements is provided above boundaries of the P-type well 4 and the N-type well 5. A channel separating section 13A is formed from a bottom surface of the channel separating section 6 (LOCOS region) . The depth of the channel separating section 13A is shallower than that of the channel separating section 13 according to Embodiment 1, and a tip portion of the channel separating section 13A may not reach the semiconductor substrate 2 of an impurity concentration region of 1×10¹⁸ cm⁻³ to 1×10¹⁹ cm⁻³, and more preferably 5×10¹⁸ cm⁻³ to 1×10¹⁹ cm⁻³, and the tip portion may be in the middle of the epitaxial layer 3. In summary, electrons will not pass under the channel separating section 13A when the high impurity concentration region of the semiconductor substrate 2 is diffused to the side towards the epitaxial layer 3 by thermal treatment, the deep channel separating section 13A lies in the well boundary, and the tip portion of the channel separating section 13A reaches the diffused impurity concentration region of 1×10¹⁸ cm⁻³ to 1×10¹⁹ cm⁻³, and more preferably 5×10¹⁸ cm⁻³ to 1×10¹⁹ cm⁻³. As described above, the semiconductor apparatus 1A has a CMOS structure with the P-type well 4 and the N-type well 5. In a NMOS transistor 7, a gate electrode 10 is provided on the P-type well 4 with a gate insulation film 9 interposed therebetween, and N+ regions 11 are provided on both sides thereof, as a source region and a drain region. Further, in a PMOS transistor 8, a gate electrode 10 is provided on the N-type well 5 with a gate insulation film 9 interposed therebetween, and P+ regions 12 are provided on both sides thereof, as a source region and a drain region.

A manufacturing method for a high-voltage resisting semiconductor apparatus 1A having the structures above will be described hereinafter.

First, an epitaxial layer 3 of a thickness of 4 μm to 8 μm, for example, is formed on a semiconductor substrate 2 with impurity concentration of 1×10¹⁸ cm⁻³ to 1×10¹⁹ cm⁻³. A channel is formed by etching up to a depth in the middle of the epitaxial layer 3 at a position to be a well boundary. As to the channel depth of the well boundary, when the high impurity concentration of the semiconductor substrate 2 is diffused to the epitaxial layer 3 and the region of the epitaxial layer 3 closer to the semiconductor substrate 2 has high impurity concentration in a later thermal treatment step, the bottom portion of the channel needs to be reaching the high impurity concentration region diffused to the epitaxial layer 3. As a matter of course, the impurity concentration of the high impurity concentration region 3a diffused to the epitaxial layer 3 is 1×10¹⁸ cm⁻³ to 1×10¹⁹ cm⁻³, and more preferably 5×10¹⁸ cm⁻³ to 1×10¹⁹ cm⁻³.

After the forming of the channel, an insulation film for separating elements is filled inside the channel . A recess portion is formed at each position, such as in between transistors for separating elements, and an insulation film is filled within the recess portion to form a channel separating section 6. Further, respective impurity ions are implanted into a region to be a P-type well 4 and a region to be an N-type well 5, in the upper part of the epitaxial layer 3, with the channel separating section 13A as a boundary.

After these ion implantations, a thermal diffusion treatment is performed to forma P-type well 4 and an N-type well 5. This thermal diffusion treatment may be performed in inactive gas at 950° C. for 60 minutes, or the thermal diffusion treatment may be combined with a thermal treatment during thermal oxidation for forming a gate insulation film, which will be explained later. At this stage, the high impurity concentration region of the semiconductor substrate 2 is diffused to the epitaxial layer 3 and the lower part of the epitaxial layer 3 becomes a high impurity concentration region 3a. As mentioned earlier, the impurity concentration of the high impurity concentration region 3a is 1×10¹⁸ cm⁻³ to 1×10¹⁹ cm⁻³, and more preferably 5×10¹⁸ cm⁻³ to 1×10¹⁹ cm⁻³. The tip portion of the channel separating section 13A needs to be reaching the high impurity concentration region 3a.

Subsequently, a gate insulation film 9 is formed on the epitaxial layer 3 and a gate electrode 10 is formed thereon. Further, N+ regions 11 are formed in regions in the P-type well 4 and on both sides of the gate electrode 10, and P+ regions 12 are formed in regions in the N-type well 5 and on both sides of the gate electrode 10. As a result, a channel separating section 13A is formed in the boundary of the P-type well 4 and the N-type well 5, and with the tip portion thereof reaching an high impurity concentration region, an NMOS transistor 7 and a PMOS transistor 8 of a CMOS structure are formed.

For the following step, a wiring layer is formed to be connected to the NMOS transistor 7 and the PMOS transistor 8 of a CMOS structure, thus a CMOS circuit is completed.

In summary, the manufacturing method for the semiconductor apparatus 1A is a manufacturing method for a semiconductor apparatus 1A of a CMOS structure having an N-type well 5 and a P-type well 4, comprising: an epitaxial growth step of growing an epitaxial layer 3 on a semiconductor substrate 2, as a first semiconductor substrate which is a high impurity concentration region with impurity concentration of 1×10¹⁷ cm⁻³ to 1×10¹⁹ cm⁻³; a first channel forming step of forming a first trench 13a, as a first channel, in a boundary section of the N-type well 5 and the P-type well 4 with a depth shallower than the thickness of the epitaxial layer 3; a second channel forming step of forming a second channel shallower than the first trench 13a; a channel separating section forming step of forming a channel separating section 13A as a first channel separating section and a channel separating section 6 as a second channel separating section, for separating elements, by filling the first trench 13a and the second channel with an identical insulating material or different insulating materials, or by forming an insulation film on inner and bottom surfaces of the trench 13a and second channel and subsequently filling a conductive material into the interior thereof ; a well region forming step of forming the N-type well 5 and the P-type well 4 shallower than the depth of the first trench 13a and deeper than the depth of the second channel; and a thermal treatment step of diffusing impurities from the semiconductor substrate 2 to the epitaxial layer 3 to allow a tip portion of the channel separating section 13A to reach the high impurity concentration region thereof.

From the foregoing, according to Embodiment 2, a semiconductor substrate 2 with high impurity concentration of 1×10¹⁷ cm⁻³ to 1×10¹⁹ cm⁻³ is used and heat treatment is performed on the semiconductor substrate 2, so that the high impurity concentration of the semiconductor substrate 2 can be diffused to the epitaxial layer 3 and the high impurity concentration region 3a can be formed below the epitaxial layer 3. Thus, the channel separating section 13A provided at the boundary of the P-type well 4 and the N-type well 5 of a CMOS structure can be shallower than the depth of the channel separating section 13 according to Embodiment 1, which facilitates the manufacturing steps. In this case, the tip portion of the channel separating section 13A is formed such that it reaches the high impurity concentration region 3a of the epitaxial layer 3. As a result, electrons will not pass though a region that is deeper than the channel separating section 13A (below the channel separating section 13A) as happens conventionally. Further, it becomes unnecessary to embed an N+ embedded layer or a P+ embedded layer deep in the substrate within a well region as is conventionally done. A CMOS structure that is more resistant to latch-up can be obtained using a simple method, and a semiconductor apparatus 1A excellent in both cost effectiveness and performance can be obtained.

In Embodiments 1 and 2, a case has been described where a high impurity concentration region with impurity concentration of 1×10¹⁸ cm⁻³ to 1×10¹⁹ cm⁻³, and more preferably 5×10¹⁸ cm⁻³ to 1×10¹⁹ cm⁻³ is used and the tip portion of the channel separating section 13 or 13A at the boundary of the P-type well 4 and the N-type well 5 is formed to reach the high impurity concentration region (high impurity concentration region of the semiconductor substrate 2 or high impurity concentration region 3a of the epitaxial layer 3) . However, without the limitation to this, even if the impurity concentration of the high impurity concentration region is lower than 1×10¹⁸ cm⁻³, e.g., 1×10¹⁷ cm⁻³, and even if the effect of the present invention is not as high as that of Embodiment 1 or 2 in terms of latch-up resistance, a CMOS structure relatively resistant to latch-up can be obtained using a simple method, and a semiconductor apparatus 1 or 1A excellent in both cost effectiveness and performance can be obtained. When this impurity concentration range is also included, the impurity concentration of the semiconductor substrate 2 or the impurity concentration of the high impurity concentration region 3a of the epitaxial layer 3 can be from 1×10¹⁸ cm⁻³ to 1×10¹⁹ cm⁻³.

The conventional method alone for deepening a channel separating section to gain a distance for trapping is not effective against latch-up. In addition to this, the impurity concentration of a region for trapping is increased to greater than or equal to a given value in Embodiments 1 and 2. Specifically, the impurity concentration of the semiconductor substrate 2 or the impurity concentration of the high impurity concentration region 3a of the epitaxial layer 3 is from 1×10¹⁷ cm⁻³ to 1×10¹⁹ cm⁻³, but in detail, P-type impurities such as boron and indium may also be used, and N-type impurities such as phosphor, arsenic and antimony may also be used. This is because latch-up starts to work at a transistor amplification value of pnpHfe x npnHfe as illustrated in FIG. 2, and latch-up becomes less likely to occur as the transistor amplification value of pnpHfe×npnHfe becomes smaller. When the P-type impurity concentration is high, the transistor amplification value of npnHfe becomes small. When the N-type impurity concentration is high, the transistor amplification value of pnpHfe becomes small.

In Embodiments 1 and 2, a case has been described where an epitaxial layer 3 is formed on a semiconductor substrate 2 with a high impurity concentration region of impurity concentration from 1×10¹⁷ cm⁻³ to 1×10¹⁹ cm⁻³, preferably from 1×10¹⁸ cm⁻³ to 1×10¹⁹ cm⁻³, and more preferably from 5×10¹⁸ cm⁻³ to 1×10¹⁹ cm⁻³. However, without the limitation to this, a high impurity concentration region with impurity concentration from 1×10¹⁷ cm⁻³ to 1×10¹⁹ cm⁻³, preferably from 1×10¹⁸ cm⁻³ to 1×10¹⁹ cm⁻³, and more preferably from 5×10¹⁷ cm⁻³ to 1×10¹⁹ cm⁻³, can be provided in a part of region or a part of a layer region, in a plane view, of a semiconductor substrate as a second semiconductor substrate. An objective of the present invention can be achieved even by forming an epitaxial layer 3 thereon.

In Embodiments 1 and 2, as a specific example thereof, a case has been described where a tip portion or a bottom surface portion of a channel separating section 13 or 13A as a first channel separating section is inserted by 1 μm into a high impurity concentration region with impurity concentration from 1×10¹⁷ cm⁻³ to 1×10¹⁹ cm⁻³, preferably from 1×10¹⁸ cm⁻³ to 1×10¹⁹ cm⁻³, and more preferably from 5×10¹⁸ cm⁻³ to 1×10¹⁹ cm⁻³. However, without the limitation to this, the tip portion or bottom surface portion of the channel separating section 13 or 13A may reach at least the upper limit boundary section of the high impurity concentration region. Specifically, the tip portion or bottom surface portion of the channel separating section 13 or 13A may contact or may be in, by 0 to 2 μm, the high impurity concentration region with impurity concentration from 1×10¹⁷ cm⁻³ to 1×10¹⁹ cm⁻³, preferably from 1×10¹⁸ cm⁻³ to 1×10¹⁹ cm⁻³, and more preferably from 5×10¹⁸ cm⁻³ to 1×10¹⁹ cm⁻³.

Although not specifically described in Embodiment 1 or 2, a structure in a plane view of a channel separating section 13 or 13A at the boundary of a P-type well 4 and an N-type well 5 in Embodiments 1 and 2 will be described hereinafter.

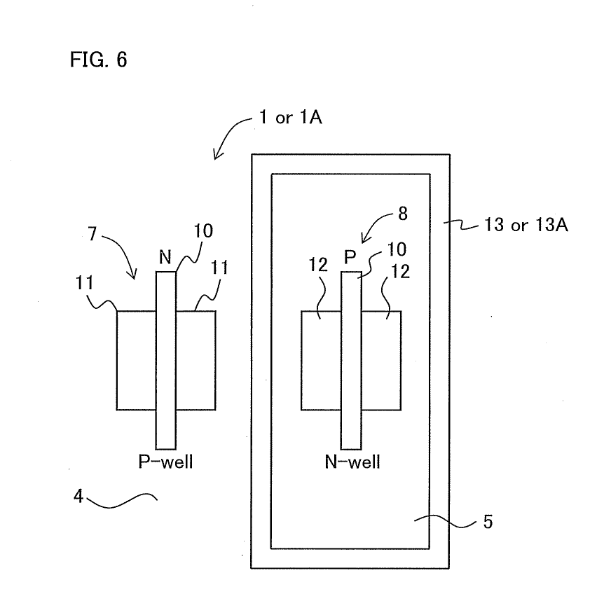

FIG. 6 is a plane view schematically illustrating a structure in a plane view of a high-voltage resisting semiconductor apparatus 1 or 1A in FIG. 1 or 5.

In a semiconductor apparatus 1 or 1A in FIG. 6, the apparatus has a CMOS structure having a P-type well 4 and an N-type well 5, as mentioned before. In an NMOS transistor 7, a gate electrode 10 is provided above the P-type well 4 with a gate insulation film 9 interposed therebetween, and N+ regions 11 are respectively provided on both sides thereof, as a source region and a drain region. Further, in an PMOS transistor 8, a gate electrode 10 is provided above the N-type well 5 with a gate insulation film 9 interposed therebetween, and P+ regions 12 are respectively provided on both sides thereof, as a source region and a drain region. In this case, in a plane view, a channel separating section 13 or 13A, surrounds the PMOS transistor 8 formed on the N-type well 5. Thereby, a CMOS structure that is resistant to latch-up can be obtained, and a semiconductor apparatus 1 or 1A excellent in both cost effectiveness and performance can be obtained with a simple configuration.

With regard to FIG. 6 and in a plane view, a case has been described where a channel separating section 13 or 13A is formed surrounding a PMOS transistor 8 formed on an N-type well 5. However, without the limitation to this, a channel separating section 13 or 13A may be formed linearly in between a PMOS transistor 8 formed on an N-type well 5 and an NMOS transistor 7 formed on a P-type well 4.

As such, in Embodiments 1 and 2, a channel separating section 13 or 13A is formed deeply at a boundary between a P-type well 4 and an N-type well 5 in a CMOS structure, up to a high impurity concentration region, so that latch-up of parasitic thyristor at the well boundary section can be prevented. However, it is not possible to prevent at all a large current from flowing through a parasitic transistor within at least either one of the P-type well 4 or the N-type well 5.

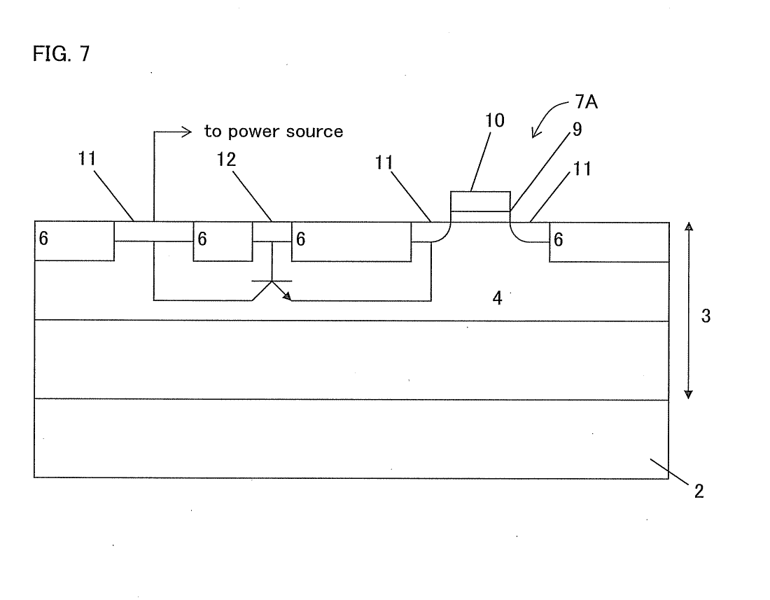

Specifically, the inventor found that other than latch-up of a parasitic thyristor at a well boundary, a parasitic NPN transistor within the P-type well 4, for example, is turned on by an external surge and a large current flows, resulting in breakdown in the worst case. The following cross sectional view in FIG. 7 illustrates an equivalent parasitic NPN transistor of a parasitic bipolar transistor. Not only countermeasures for latch-up at the well boundary as in Embodiments 1 and 2, but also countermeasures for latch-up of a parasitic NPN transistor as illustrated in the following Embodiment 3 are necessary.

FIG. 7 is a longitudinal cross sectional view of an essential part of a semiconductor apparatus, illustrating an exemplary equalizing circuit of a parasitic NPN transistor formed within a P-type well 4.

In FIG. 7 with a case where a power source voltage output terminal is connected to an N+ region 11 in an NPN structure within a P-type well 4, as an equalizing circuit of the parasitic NPN transistor, a parasitic NPN transistor is formed in which a collector is connected to the N+ region 11, a base is connected to a P+ region 12, and an emitter is connected to another N+ region 11 (N+ region 11 of an output NMOS transistor 7A). If the parasitic NPN transistor is turned on by an external surge, a large current may flow through the parasitic NPN transistor.

The following Embodiment 3 illustrates a case for solving this problem, where a channel separating section 13 or 13A of Embodiment 1 or 2, which extends deeper than a channel separating section 6 (LOCOS region) for separating elements, separates an N+ region 11 (e.g., ESD protecting N+ diode) directly connected to a power source voltage output terminal, through which a large current may flow, in the NPN structure within the P-type well 4, from an N+ region 11 of an output NMOS transistor 7A. Also in this case, a tip portion of the channel separating section 13 or 13A, which is positioned deeper than the channel separating section 6 (LOCOS region) for separating elements, is at a depth which allows the tip portion to reach at least a layer with impurity concentration of 1×10¹⁷ cm⁻³ to 1×10¹⁹ cm⁻³, as similar to the cases in Embodiments 1 and 2.

### Embodiment 3

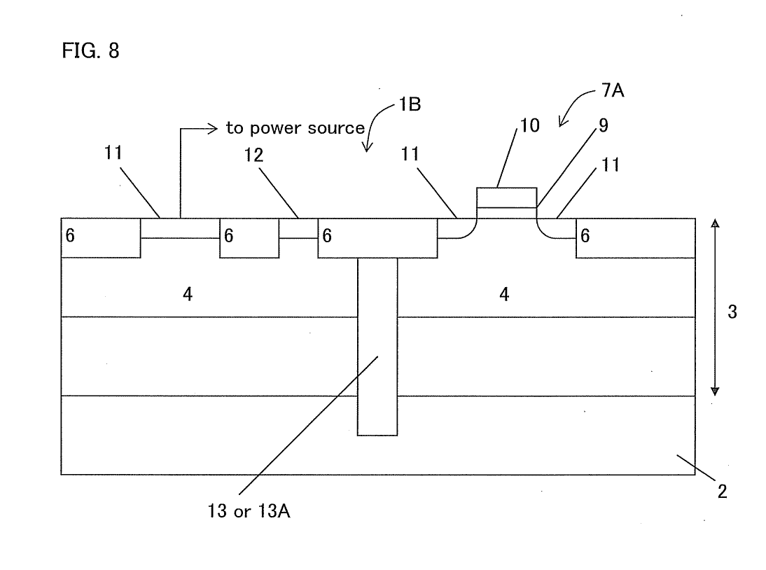

FIG. 8 is a longitudinal cross sectional view illustrating an exemplary structure of an essential part of a high-voltage resisting semiconductor apparatus according to Embodiment 3 of the present invention. The same reference numerals are used for the structural members that indicate the same functional effects as those of the structural members in FIGS. 1 and 5.

In FIG. 8, a high-voltage resisting semiconductor apparatus 18 according to Embodiment 3 comprises an epitaxial layer 3 formed by epitaxial growth on a semiconductor substrate 2 of high impurity concentration. In the upper part of the epitaxial layer 3, a P-type well 4 is formed as a well of one of the conductive types. In the P-type well 4, the structure is such that a channel separating section 13 or 13A, which extends deeper than a channel separating section 6 (LOCOS region) for separating elements, separates an N+ region 11 (e.g., ESD protecting N+ diode) directly connected to a power source voltage output terminal, from an N+ region 11 of an output NMOS transistor 7A. The channel separating section 6 (LOCOS region) for separating elements is provided for separating elements, at a boundary between an N+ region 11 directly connected to a power source voltage output terminal and a P+ region 12, and a boundary between a P+ region 12 and an N+ region 11 of an output NMOS transistor 7A. The channel separating section 13 or 13A is further provided from the bottom portion of the channel separating section 6. The output NMOS transistor 7A is provided in between the channel separating sections 6 (LOCOS regions) on the right side. In the output NMOS transistor 7A, a gate electrode 10 is provided above the P-type well 4 with a gate insulation film 9 interposed therebetween, and N+ regions 11 are respectively provided on both sides thereof, as a source region and a drain region.

In summary, the high-voltage resisting semiconductor apparatus 1B according to Embodiment 3 comprises: a channel separating section 6 (LOCOS region) for separating elements; and a channel separating section 13 or 13A which is positioned deeper than the channel separating section 6. Further, the high-voltage resisting semiconductor apparatus 1B comprises an N+ region 11 (e.g., ESD protecting N+ diode) directly connected to a power source voltage output terminal; and an output NMOS transistor 7A, where the channel separating section 13 or 13A is provided in between the N+ region 11 directly connected to a power source voltage output terminal, and the output NMOS transistor 7A. In this case, the tip portion of the channel separating section 13 or 13A deeper than the channel separating section 6 is at a depth which allows the tip portion to reach at least a layer with impurity concentration of 1×10¹⁷ cm⁻³ to 1×10¹⁹ cm⁻³, as similar to the cases in Embodiments 1 and 2.

Similar to the cases in Embodiments 1 and 2, in the case of Embodiment 3, the tip portion or bottom surface portion of the channel separating section 13 or 13A may contact or may be in, by 0 to 2 μm, the high impurity concentration region with impurity concentration from 1×10¹⁷ cm⁻³ to 1×10¹⁹ cm⁻³, preferably from 1×10¹⁸ cm⁻³ to 1×10¹⁹ cm⁻³, and more preferably from 5×10¹⁸ cm⁻³ to 1×10¹⁹ cm⁻³.

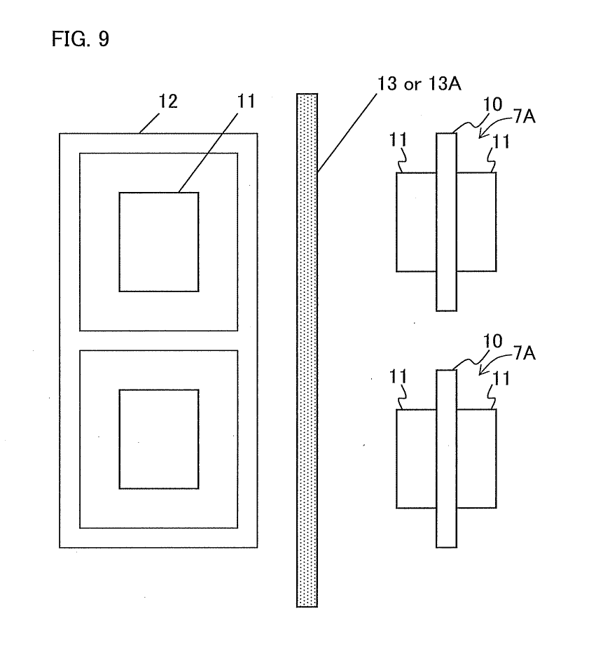

Regarding the high-voltage resisting semiconductor apparatus 1B according to Embodiment 3, a structure in a plane view of a channel separating section 13 or 13A within a P-type well 4 will be described in detail with reference to FIGS. 9 to 12.

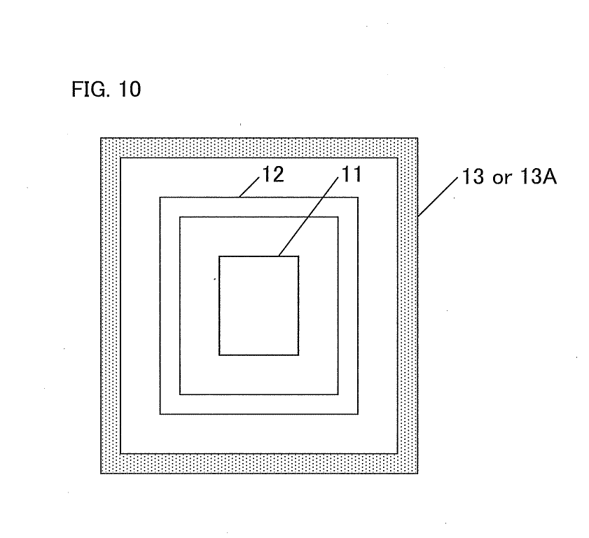

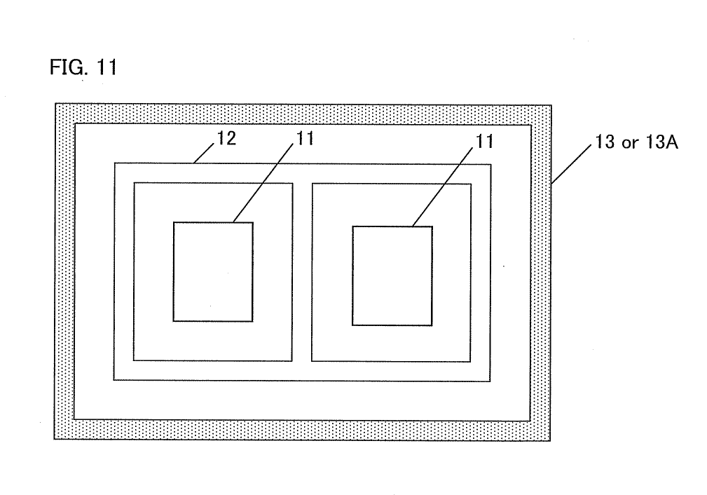

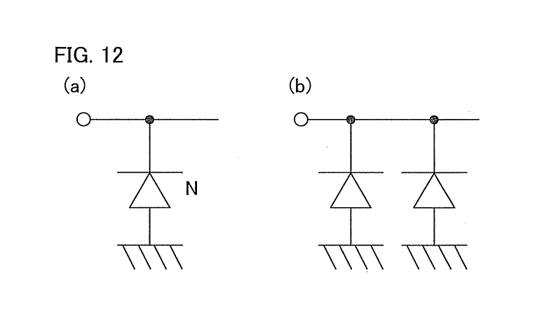

FIG. 9 is a plane view schematically illustrating an example of a structure in a plane view of the high-voltage resisting semiconductor apparatus 1B in FIG. 8. FIG. 10 is a plane view schematically illustrating an example of a structure in a plane view of a single N+ diode. FIG. 11 is a plane view schematically illustrating an example of a structure in a plane view of two N+ diodes in parallel to each other. FIG. 12(a) is a circuit diagram illustrating an equalizing circuit of a single N+ diode in FIG. 10. FIG. 12(b) is a circuit diagram illustrating an equalizing circuit of two N+ diodes in parallel to each other in FIG. 11.

As illustrated in FIG. 9, in a plane view, the channel separating section 13 or 13A according to Embodiment 1 or 2 is linearly formed in between two N+ diodes in parallel to each other for protection (an N+ region 11 directly connected to a power source voltage output terminal and a P+ region 12) and two output NMOS transistors 7A, for example, and a current is blocked not to flow from an N+ region 11 directly connected to a power source voltage output terminal to an N+ region 11 of the output NMOS transistor 7A. Thereby, an NPN structure resistant to latch-up can be obtained, and a semiconductor apparatus 1B excellent in both cost effectiveness and performance can be obtained with a simple configuration.

In addition, as illustrated in FIGS. 10 and 11, the channel separating section 13 or 13A is formed in a rectangular ring shape surrounding a N+ region 11 directly connected to a power source voltage output terminal, and a P+ region 12, which constitute either a single N+ diode or two N+ diodes in parallel to each other; and a current is blocked not to flow from an N+ region 11 directly connected to a power source voltage output terminal to an N+ region 11 of the output NMOS transistor 7A. In this case, similar to the linear channel separating section 13 or 13A in FIG. 9, a current from the N+ region 11 directly connected to a power source voltage output terminal, flowing around to the N+ region 11 of the output NMOS transistor 7A can be prevented.

FIG. 12(a) illustrates an equalizing circuit of the single N+ diode in FIG. 10, while FIG. 12(b) illustrates an equalizing circuit of two equalizing circuits in parallel to each other in FIG. 11 for gaining current capacity. However, without a limitation to such two equalizing circuits in parallel to each other, three or more equalizing circuits in parallel to one another may be formed. A structure is such that a P+ region 12 is arranged around an N+ region 11 directly connected to one or a plurality of power source voltage output terminals, and a channel separating section 13 or 13A is arranged around the P+ region 12. When the P+ region 12 surrounding the N+ region 11 is surrounded, it can cope with the N+ region 11 of the output NMOS transistor 7A being located in any direction. Further, it can cope with a large current flowing because of an encircling carrier implanted in a base region. Regarding the depth of the channel separating section 13 or 13A, similar to the case where it is arranged at a well boundary as in Embodiments 1 and 2, the channel separating section 13 or 13A is arranged at or deeper than a depth which allows it to reach a semiconductor substrate 2 with impurity concentration from 1×10¹⁷ cm⁻³ to 1×10¹⁹ cm⁻³. While the channel separating section 13 or 13A may be arranged only at a well boundary section as in Embodiments 1 and 2, it may also be arranged both at a well boundary section and in between the N+ region 11 directly connected to a power source voltage output terminal, and the N+ region 11 of the output NMOS transistor 7A. Either way, the depth of these elements is the same, and therefore, they can be formed in the same step.

A manufacturing method for a semiconductor apparatus 1B of the present invention will be described hereinafter.

Regarding the channel separating section 13 according to Embodiment 1, a manufacturing method for a semiconductor apparatus 1B having a P-type well 4 and an N-type well 5, comprising an epitaxial growth step of growing an epitaxial layer 3 on a first semiconductor substrate 2, which is a high impurity concentration region with impurity concentration of 1×10¹⁷ cm⁻³ to 1×10¹⁹ cm⁻³, or a second semiconductor substrate having a high impurity concentration region; a first channel forming step of forming a first channel, at the same depth as the epitaxial layer 3 or a depth penetrating the epitaxial layer 3 and reaching the high impurity concentration region of the first semiconductor substrate 2 or the second semiconductor substrate, at least either between an N+ region 11 connected to a power source voltage output terminal and an N+ region 11 of an output NMOS transistor 7A, or between a P-type region connected to the power source voltage output terminal and a P-type region of a PMOS transistor, or in such a manner to surround at least either of the N+ region 11 or the P-type region connected to the power source voltage output terminal; a second channel forming step of forming a second channel shallower than the first channel; a channel separating section forming step of forming a first channel separating section 13 and a second channel separating section 6, for separating elements, by filling the first channel and the second channel with an identical insulating material or different insulating materials, or by forming an insulation film on inner and bottom surfaces of the first channel and second channel and subsequently filling a conductive material into the interior thereof; and a well region forming step of forming the N-type well 5 and the P-type well 4 shallower than the depth of the first channel and deeper than the depth of the second channel.

Next, regarding the channel separating section 13A according to Embodiment 2, a manufacturing method for a semiconductor apparatus 1B having a P-type well 4 and an N-type well 5, comprising an epitaxial growth step of growing an epitaxial layer 3 on a first semiconductor 2, which is a high impurity concentration region with impurity concentration of 1×10¹⁷ cm⁻³ to 1×10¹⁹ cm⁻³, or a second semiconductor substrate having a high impurity concentration region; a first channel forming step of forming a first channel, at a depth shallower than a thickness of the epitaxial layer 3, at least either between an N₊ region 11 connected to a power source voltage output terminal and an N+ region 11 of an output NMOS transistor 7A, or a P-type region connected to the power source voltage output terminal and a P-type region of a PMOS transistor, or in such a manner to surround at least either of the N₊ region 11 or the P-type region connected to the power source voltage output terminal; a second channel forming step of forming a second channel shallower than the first channel; a channel separating section forming step of forming a first channel separating section 13a and a second channel separating section 6, for separating elements, by filling the first channel and the second channel with an identical insulating material or different insulating materials, or by forming an insulation film on inner and bottom surfaces of the first channel and second channel and subsequently filling a conductive material into the interior thereof; and a well region forming step of forming an N-type well 5 and a P-type well 4 shallower than the depth of the first channel and deeper than the depth of the second channel; and a thermal treatment step of diffusing impurities by thermal treatment from the first semiconductor substrate 2 or the second semiconductor substrate to the epitaxial layer 3 to allow a tip portion of the first channel separating section 13A to reach the high impurity concentration region thereof.

As described above, according to Embodiment 3, within the P-type well 4, the channel separating section 13 or 13A is formed between the N+ region 11 ESD protection diode of an N+/P− structure for releasing surge from a power source to the ground) directly connected to a power source terminal and the output NMOS transistor 7A, or the channel separating section 13 or 13A surrounds the N+ region 11 directly connected to a power source terminal and the P+ region 12 around the N+ region 11. The tip portion of the channel separating section 13 or 13A has a depth reaching at least a layer with impurity concentration of 1×10¹⁷ cm⁻³ to 1×10¹⁹ cm⁻³.

Therefore, in addition, to or apart from an on-state preventing function of a parasitic thyristor at a well boundary according to Embodiments 1 and 2, an on-state of a parasitic NMOS transistor can be further prevented as in Embodiment 3. Thereby, a CMOS structure more resistant to latch-up can be obtained with simple steps, and in addition to or apart from this, an NMOS structure more resistant to latch-up can be obtained with simple steps.

In Embodiment 3, a case has been described with a semiconductor apparatus 1B having at least a P-type well 4, where impurity concentration of a high impurity concentration region (e.g., semiconductor substrate 2) deeper than the P-type well 4 is from 1×10¹⁷ cm⁻³ to 1×10¹⁹ cm⁻³; the semiconductor apparatus 1B comprises a channel separating section 13 or 13A, as a first channel separating section and a channel separating section 6 as a second channel separating section, for separating elements; the channel separating section 13 or 13A being arranged in a plane view linearly in between an N+ region 11, as a region of the other conductivity connected to a power source voltage output terminal, and an N+ region 11, as a region of the other conductivity connected to an NMOS transistor 7A, within the P-type well 4, or being arranged in such a manner to surround an N+ region 11, as a region of the other conductivity connected to a power source voltage output terminal; the depth of the channel separating section 13 or 13A being formed deeper than the depth of the channel separating section 6; and the depth of the channel separating section 13 or 13A being formed equal to or deeper than the depth of the high impurity concentration region. In addition to or apart from this, impurity concentration of a high impurity concentration region (e.g., semiconductor substrate 2) deeper than an N-type well 5 may be from 1×10¹⁷ cm⁻³ to 1×10¹⁹ cm⁻³; the semiconductor apparatus 1B may comprise a channel separating section 13 or 13A as a first channel separating section and a channel separating section 6 as a second channel separating section, for separating elements; the channel separating section 13 or 13A being arranged in a plane view linearly in between a P+ region 12, as a region of the other conductivity connected to a power source voltage output terminal, and a P+ region 12, as a region of the other conductivity connected to a PMOS transistor, within an N-type well 5, or being arranged in such a manner to surround an P+ region 12, as a region of the other conductivity connected to a power source voltage output terminal; the depth of the channel separating section 13 or 13A being formed deeper than the depth of the channel separating section 6; and the depth of the channel separating section 13 or 13A being formed equal to or deeper than the depth of the high impurity concentration region.

In summary, the channel separating section 13 or 13A is arranged in a plane view linearly in between an N+region 11 connected to a power source voltage output terminal, and an N+ region 11 of an NMOS transistor 7A, within the 2-type well 4, or is arranged in such a manner to surround a P+ region 12 around the N+ region 11 connected to a power source voltage output terminal. This is for preventing a current from flowing between an N+ region 11 of an ESD protection N+ diode and an output NMOS transistor 7A, for example, with the 2-type well 4.

Accordingly, the semiconductor apparatus 1B according to Embodiment 3 is a semiconductor apparatus having a P-type well and an N-type well, where impurity concentration of a high impurity concentration region deeper than the P-type well or the N-type well is from 1×10¹⁷ cm⁻³ to 1×10¹⁹ cm⁻³; the apparatus comprises a first channel separating section and a second channel separating section for separating elements; the first channel separating section is arranged, in a plane view, at least either between an N-type region connected to a power source voltage output terminal and an N-type region of an NMOS transistor, or between a P-type region connected to a power source voltage output terminal and a P-type region of a PMOS transistor, at least within either the P-type well or the N-type well, or arranged in such a manner to surround at least either of the N-type region or the P-type region connected to the power source voltage output terminal; a depth of the first channel separating section is formed deeper than the second channel separating section; and a depth of the first channel separating section is formed equal to or deeper than the high impurity concentration region.

As described above, the present invention is exemplified by the use of its preferred Embodiments 1 to 3. However, the present invention should not be interpreted solely based on Embodiments 1 to 3 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 3 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a high-voltage resisting semiconductor apparatus of a CMOS structure, such as a liquid crystal driver, and a manufacturing method thereof. According to the present invention, a semiconductor substrate with high impurity concentration of 1×10¹⁷ cm⁻³ to 1×10¹⁹ cm⁻³ is used, and a tip portion of a first channel separating section, provided at a well boundary of a P-type well and an N-type well, of a CMOS structure, is formed at a depth reaching the high impurity concentration region. Thus, electrons will not pass though a region that is deeper than the first channel separating section as happens conventionally. Further, it becomes unnecessary to newly embed an N+ embedded layer or a P+ embedded layer deep in the substrate within the well region, as is conventionally done. As a result, a CMOS structure that is more resistant to latch-up can be obtained using a simple method, and a semiconductor apparatus excellent in both cost effectiveness and performance can be obtained.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A semiconductor apparatus having a P-type well and an N-type well, with impurity concentration of a high impurity concentration region deeper than the P-type well and the N-type well being from 1×10¹⁷ cm⁻³ to 1×10¹⁹ cm⁻³, and the apparatus comprising a first channel separating section for separating elements, a depth of the first channel separating section being equal to or deeper than the high impurity concentration region.

2. A semiconductor apparatus of a CMOS structure having a P-type well and an N-type well according to claim 1, wherein the apparatus comprises a second channel separating section for separating elements, the first channel separating section being at a boundary of the N-type well and the P-type well, a depth of the first channel separating section being deeper than a depth of the second channel separating section.

3. A semiconductor apparatus according to claim 1, wherein: the apparatus comprises a second channel separating section for separating elements; the first channel separating section is arranged, in a plane view, at least either between an N-type region connected to a power source voltage output terminal and an N-type region of an NMOS transistor, or between a P-type region connected to the power source voltage output terminal and a P-type region of a PMOS transistor, at least within either the P-type well or the N-type well, or arranged in such a manner to surround at least either of the N-type region or the P-type region connected to the power source voltage output terminal; and a depth of the first channel separating section is deeper than a depth of the second channel separating section.

4. A semiconductor apparatus according to claim 2, wherein: an epitaxial layer is provided on a semiconductor substrate; the P-type well and the N-type well are provided in an upper part of the epitaxial layer; an NMOS transistor is provided within the P-type well in between the second channel separating sections; and a PMOS transistor is provided within the N-type well in between the second channel separating sections.

5. A semiconductor apparatus according to claim 3, wherein: an epitaxial layer is provided on a semiconductor substrate; the P-type well and the N-type well are provided in an upper part of the epitaxial layer; an NMOS transistor is provided within the P-type well in between the second channel separating sections; and a PMOS transistor is provided within the N-type well in between the second channel separating sections.

6. A semiconductor apparatus according to claim 4, wherein the semiconductor substrate is the high impurity concentration region, or the high impurity concentration region is arranged in the semiconductor substrate.

7. A semiconductor apparatus according to claim 5, wherein the semiconductor substrate is the high impurity concentration region, or the high impurity concentration region is arranged in the semiconductor substrate.

8. A semiconductor apparatus according to claim 4, wherein a partial region of the epitaxial layer thermally diffused from the semiconductor substrate to the epitaxial layer is the high impurity concentration region.

9. A semiconductor apparatus according to claim 5, wherein a partial region of the epitaxial layer thermally diffused from the semiconductor substrate to the epitaxial layer is the high impurity concentration region.

10. A semiconductor apparatus according to claim 6, wherein the depth of the first channel separating section is deeper than a depth reaching a region of the semiconductor substrate, or the depth of the first channel separating section is deeper than a depth of the partial region of the epitaxial layer thermally diffused from the semiconductor substrate.

11. A semiconductor apparatus according to claim 8, wherein the depth of the first channel separating section is deeper than a depth reaching a region of the semiconductor substrate, or the depth of the first channel separating section is deeper than a depth of the partial region of the epitaxial layer thermally diffused from the semiconductor substrate.

12. A semiconductor apparatus according to claim 7, wherein the depth of the first channel separating section is deeper than a depth reaching a region of the semiconductor substrate, or the depth of the first channel separating section is deeper than a depth of the partial region of the epitaxial layer thermally diffused from the semiconductor substrate.

13. A semiconductor apparatus according to claim 9, wherein the depth of the first channel separating section is deeper than a depth reaching a region of the semiconductor substrate, or the depth of the first channel separating section is deeper than a depth of the partial region of the epitaxial layer thermally diffused from the semiconductor substrate.

14. A semiconductor apparatus according to claim 1, wherein a tip portion or a bottom surface portion of the first channel separating section reaches at least an upper limit boundary section of the high impurity concentration region.

15. A semiconductor apparatus according to claim 14, wherein the tip portion or the bottom surface portion of the first channel separating section contacts or is in the high impurity concentration region, by 0 to 2 μm.

16. A semiconductor apparatus according to claim 1, wherein the impurity concentration of the high impurity concentration region is from 1×10¹⁸ cm⁻³ to 1×10¹⁹ cm⁻³.

17. A semiconductor apparatus according to claim 1, wherein the impurity concentration of the high impurity concentration region is from 5×10¹⁷ cm⁻³ to 1×10¹⁹ cm⁻³.

18. A semiconductor apparatus according to claim 1, wherein the impurity is either a P-type impurity or an N-type impurity.

19. A semiconductor apparatus according to claim 18, wherein the P-type impurity is boron or indium, and the N-type impurity is phosphor, arsenic or antimony.

20. A semiconductor apparatus according to claim 2, wherein the first channel separating section is formed deeper than the bottom surface portion of the second channel separating section.

21. A semiconductor apparatus according to claim 2, wherein the first channel separating section is arranged in between an NMOS transistor formed within the P-type well and a PMOS transistor formed within the N-type well, or is arranged in such a manner to surround the PMOS transistor.

22. A manufacturing method for a semiconductor apparatus of a CMOS structure having an N-type well and a P-type well, comprising:
an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region;
a first channel forming step of forming a first channel in a boundary section of the N-type well and the P-type well with a depth as deep as the epitaxial layer or with a depth penetrating the epitaxial layer and reaching the high impurity concentration region of the first semiconductor substrate or the second semiconductor substrate;
a second channel forming step of forming a second channel shallower than the first channel;
a channel separating section forming step of forming a first channel separating section and a second channel separating section, for separating elements, by filling the first channel and the second channel with an identical insulating material or different insulating materials, or by forming an insulation film on inner and bottom surfaces of the first channel and the second channel and subsequently filling a conductive material into the interior thereof; and
a well region forming step of forming the N-type well and the P-type well shallower than the depth of the first channel and deeper than the depth of the second channel.

23. A manufacturing method for a semiconductor apparatus of a CMOS structure having an N-type well and a P-type well, comprising:
an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region;
a first channel forming step of forming a first channel in a boundary section of the N-type well and the P-type well with a depth shallower than the thickness of the epitaxial layer;
a second channel forming step of forming a second channel shallower than the first channel;
a channel separating section forming step of forming a first channel separating section and a second channel separating section, for separating elements, by filling the first channel and the second channel with an identical insulating material or different insulating materials, or by forming an insulation film on inner and bottom surfaces of the first channel and second channel and subsequently filling a conductive material into the interior thereof;
a well region forming step of forming the N-type well and the P-type well shallower than the depth of the first channel and deeper than the depth of the second channel; and
a thermal treatment step of diffusing impurities from the first semiconductor substrate or the second semiconductor substrate to the epitaxial layer to allow a tip portion of the first channel separating section to reach the high impurity concentration region thereof.

24. A manufacturing method for a semiconductor apparatus having an N-type well and a P-type well, comprising:
an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region;
a first channel forming step of forming a first channel, at the same depth as the epitaxial layer or at a depth penetrating the epitaxial layer and reaching the high impurity concentration region of the first semiconductor substrate or the second semiconductor substrate, at least either between an N+ region connected to a power source voltage output terminal and an N+ region of an output NMOS transistor, or between a P-type region connected to the power source voltage output terminal and a P-type region of a PMOS transistor, or in such a manner to surround at least either of the N+ region or the P-type region connected to the power source voltage output terminal;
a second channel forming step of forming a second channel shallower than the first channel;
a channel separating section forming step of forming a first channel separating section and a second channel separating section, for separating elements, by filling the first channel and the second channel with an identical insulating material or different insulating materials, or by forming an insulation film on inner and bottom surfaces of the first channel and second channel and subsequently filling a conductive material into the interior thereof; and
a well region forming step of forming the N-type well and the P-type well shallower than the first channel and deeper than the second channel.

25. A manufacturing method for a semiconductor apparatus having an N-type well and a P-type well, comprising:
an epitaxial growth step of growing an epitaxial layer on a first semiconductor substrate, which is a high impurity concentration region with impurity concentration of 1×10¹⁷ cm⁻³ to 1×10¹⁹ cm⁻³, or a second semiconductor substrate having the high impurity concentration region;
a first channel forming step of forming a first channel, at a depth shallower than the thickness of the epitaxial layer, at least either between an N+ region connected to a power source voltage output terminal and an N+ region of an NMOS transistor, or between a P-type region connected to the power source voltage output terminal and a P-type region of a PMOS transistor, or in such a manner to surround at least either of the N+ region or the P-type region connected to the power source voltage output terminal;
a second channel forming step of forming a second channel shallower than the first channel;
a channel separating section forming step of forming a first channel separating section and a second channel separating section, for separating elements, by filling the first channel and the second channel with an identical insulating material or different insulating materials, or by forming an insulation film on inner and bottom surfaces of the first channel and second channel and subsequently filling a conductive material into the interior thereof;
a well region forming step of forming the N-type well and the P-type well shallower than the first channel and deeper than the second channel; and
a thermal treatment step of diffusing impurities, by thermal treatment, from the first semiconductor substrate or the second semiconductor substrate to the epitaxial layer to allow a tip portion of the first channel separating section to reach the high impurity concentration region thereof.

26. A manufacturing method for a semiconductor apparatus according to claim 22, wherein the depth of the first channel separating section is formed equal to or deeper than a depth reaching a region of the first semiconductor substrate or the second semiconductor substrate, or equal to or deeper than a depth of a partial region of the epitaxial layer thermally diffused from the first semiconductor substrate or the second semiconductor substrate.

27. A manufacturing method for a semiconductor apparatus according to claim 23, wherein the depth of the first channel separating section is formed equal to or deeper than a depth reaching a region of the first semiconductor substrate or the second semiconductor substrate, or equal to or deeper than a depth of a partial region of the epitaxial layer thermally diffused from the first semiconductor substrate or the second semiconductor substrate.

28. A manufacturing method for a semiconductor apparatus according to claim 24, wherein the depth of the first channel separating section is formed equal to or deeper than a depth reaching a region of the first semiconductor substrate or the second semiconductor substrate, or equal to or deeper than a depth of a partial region of the epitaxial layer thermally diffused from the first semiconductor substrate or the second semiconductor substrate.

29. A manufacturing method for a semiconductor apparatus according to claim 25, wherein the depth of the first channel separating section is formed equal to or deeper than a depth reaching a region of the first semiconductor substrate or the second semiconductor substrate, or equal to or deeper than a depth of a partial region of the epitaxial layer thermally diffused from the first semiconductor substrate or the second semiconductor substrate.

30. A manufacturing method for a semiconductor apparatus according to claim 22, wherein the first channel separating section is formed in such a manner to allow the tip portion or a bottom surface portion thereof to reach at least an upper limit boundary section of the high impurity concentration region.

31. A manufacturing method for a semiconductor apparatus according to claim 23, wherein the first channel separating section is formed in such a manner to allow the tip portion or a bottom surface portion thereof to reach at least an upper limit boundary section of the high impurity concentration region.

32. A manufacturing method for a semiconductor apparatus according to claim 24, wherein the first channel separating section is formed in such a manner to allow the tip portion or a bottom surface portion thereof to reach at least an upper limit boundary section of the high impurity concentration region.

33. A manufacturing method for a semiconductor apparatus according to claim 25, wherein the first channel separating section is formed in such a manner to allow the tip portion or a bottom surface portion thereof to reach at least an upper limit boundary section of the high impurity concentration region.

34. A manufacturing method for a semiconductor apparatus according to claim 30, wherein the first channel separating section is formed in such a manner to allow the tip portion or the bottom surface portion thereof contact or be in the high impurity concentration region, by 0 to 2 μm.

35. A manufacturing method for a semiconductor apparatus according to claim 31, wherein the first channel separating section is formed in such a manner to allow the tip portion or the bottom surface portion thereof contact or be in the high impurity concentration region, by 0 to 2 μm.

36. A manufacturing method for a semiconductor apparatus according to claim 32, wherein the first channel separating section is formed in such a manner to allow the tip portion or the bottom surface portion thereof contact or be in the high impurity concentration region, by 0 to 2 μm.

37. A manufacturing method for a semiconductor apparatus according to claim 33, wherein the first channel separating section is formed in such a manner to allow the tip portion or the bottom surface portion thereof contact or be in the high impurity concentration region, by 0 to 2 μm.

38. A manufacturing method for a semiconductor apparatus according to claim 22, wherein the impurity concentration of the high impurity concentration region is from 1×10¹⁸ cm⁻³ to 1×10¹⁹ cm⁻³.

39. A manufacturing method for a semiconductor apparatus according to claim 23, wherein the impurity concentration of the high impurity concentration region is from 1×10¹⁸ cm⁻³ to 1×10¹⁹ cm⁻³.

40. A manufacturing method for a semiconductor apparatus according to claim 24, wherein the impurity concentration of the high impurity concentration region is from 1×10¹⁸ cm⁻³ to 1×10¹⁹ cm⁻³.

41. A manufacturing method for a semiconductor apparatus according to claim 25, wherein the impurity concentration of the high impurity concentration region is from 1×10¹⁸ cm⁻³ to 1×10¹⁹ cm⁻³.

42. A manufacturing method for a semiconductor apparatus according to claim 22, wherein the impurity concentration of the high impurity concentration region is from 5×10¹⁸ cm⁻³ to 1×10¹⁹ cm⁻³.

43. A manufacturing method for a semiconductor apparatus according to claim 23, wherein the impurity concentration of the high impurity concentration region is from 5×10¹⁸ cm⁻³ to 1×10¹⁹ cm⁻³.

44. A manufacturing method for a semiconductor apparatus according to claim 24, wherein the impurity concentration of the high impurity concentration region is from 5×10¹⁸ cm⁻³ to 1×10¹⁹ cm⁻³.

45. A manufacturing method for a semiconductor apparatus according to claim 25, wherein the impurity concentration of the high impurity concentration region is from 5×10¹⁸ cm⁻³ to 1×10¹⁹ cm⁻³.

46. A manufacturing method for a semiconductor apparatus according to claim 22, wherein the impurity is either a P-type impurity or an N-type impurity.

47. A manufacturing method for a semiconductor apparatus according to claim 23, wherein the impurity is either a P-type impurity or an N-type impurity.

48. A manufacturing method for a semiconductor apparatus according to claim 24, wherein the impurity is either a P-type impurity or an N-type impurity.

49. A manufacturing method for a semiconductor apparatus according to claim 25, wherein the impurity is either a P-type impurity or an N-type impurity.
